(19) United States
(12) Patent Application Publication
(10) Pub. No.: US 2020/0072870 A1
(43) Pub. Date: Mar. 5, 2020

(54) PROBE CARD AND TEST DEVICE INCLUDING THE SAME

(71) Applicant: Samsung Display Co., Ltd., Yongin-si (KR)

(72) Inventor: Tae Yong JANG, Yongin-si (KR)

(21) Appl. No.: 16/510,741

(22) Filed: Jul. 12, 2019

(30) Foreign Application Priority Data
Aug. 29, 2018 (KR) 10-2018-0102248

(51) Int. Cl. G01R 1/073; G01R 1/067

(52) U.S. Cl. CPC G01R 1/07307; G01R 1/06766; G01R 1/06733

(57) ABSTRACT

There are provided a probe card and a test device including the same. The probe card may include a probe substrate, a plurality of cables on the probe substrate, a plurality of pins on the probe substrate, the plurality of pins being electrically connected to the plurality of cables, and a conductive line on the probe substrate, the conductive line being connected to a ground line.

### CROSS-REFERENCE TO RELATED APPLICATION

The present application claims priority to, and the benefit of, Korean patent application 10-2018-0102248 filed on Aug. 29, 2018 in the Korean Intellectual Property Office, the entire disclosure of which is incorporated herein by reference.

### BACKGROUND

### 1. Field

The present disclosure generally relates to a probe card, and a test device including the same.

### 2. Description of the Related Art

After a plurality of display elements (e.g., a transistor, a capacitor, a light emitting element, etc.) are formed on a substrate through a process of fabricating a display device, an electrical characteristic test for at least some of the display elements is performed.

The electrical characteristic test is performed through a probe card for determining whether a failure has occurred in display elements by applying an electrical signal to the display elements, and by sensing a signal output corresponding to the applied electrical signal.

### SUMMARY

Embodiments provide a probe card for reducing leakage, current and a test device including the same.

According to an aspect of the present disclosure, there is provided a probe card including a probe substrate, a plurality of cables on the probe substrate, a plurality of pins on the probe substrate, the plurality of pins being electrically connected to the plurality of cables, and a conductive line on the probe substrate, the conductive line being connected to a ground line.

The conductive line may be formed along an edge of the probe substrate.

The conductive line may have a closed curve shape.

The plurality of cables may be located in an area surrounded by the conductive line.

Each of the plurality of cables may include a conductive core, a first protective layer on the conductive core, an intermediate layer on the first protective layer, a second protective layer on the intermediate layer, and a jacket on the second protective layer.

The conductive core may be directly connected to the probe substrate.

According to another aspect of the present disclosure, there is provided a test device including a probe station for fixing an object to be measured, a probe card configured to be attached to the probe station to be electrically connected to the object to be measured, and a measurer configured to be connected to the probe card for measuring an electrical characteristic of the object to be measured, wherein the probe card includes a probe substrate, a plurality of cables on the probe substrate, and configured to be connected to the measurer, a plurality of pins on the probe substrate and electrically connected to the plurality of cables, and a conductive line on the probe substrate and connected to a ground line.

The ground line may be configured to be connected to the measurer.

The conductive line may be formed along an edge of the probe substrate.

The conductive line may have a closed curve shape.

The plurality of cables may be located in an area surrounded by the conductive line.

Each of the plurality of cables may include a conductive core, a first protective layer on the conductive core, an intermediate layer on the first protective layer, a second protective layer on the intermediate layer, and a jacket on the second protective layer.

The conductive core may be configured to be directly connected to the probe substrate.

The object to be measured may be at least one of a transistor and a capacitor that are included in a pixel in an organic light emitting display device.

The plurality of pins may be configured to be in direct contact with the object to be measured.

Accordingly, the disclosed embodiments are able to reduce an unwanted influence otherwise caused by leakage current.

### BRIEF DESCRIPTION OF THE DRAWINGS

Example embodiments will now be described more fully hereinafter with reference to the accompanying drawings, in which:

FIG. 1 is a view illustrating a configuration of a test device according to an embodiment of the present disclosure;

FIGS. 2 and 3 are views illustrating a configuration of a probe card according to an embodiment of the present disclosure;

FIG. 4 is a sectional view of a cable shown in FIGS. 2 and 3;

FIG. 5 is a view schematically illustrating a configuration of a display device;

FIG. 6 is a view illustrating an embodiment of a pixel shown in FIG. 5; and

FIG. 7 is a view illustrating a pad for testing an electrical characteristic of an element included in the pixel.

### DETAILED DESCRIPTION

Features of the inventive concept and methods of accomplishing the same may be understood more readily by reference to the detailed description of embodiments and the accompanying drawings. Hereinafter, embodiments will be described in more detail with reference to the accompanying drawings. The described embodiments, however, may be embodied in various different forms, and should not be construed as being limited to only the illustrated embodiments herein. Rather, these embodiments are provided as examples so that this disclosure will be thorough and complete, and will fully convey the aspects and features of the present inventive concept to those skilled in the art. Accordingly, processes, elements, and techniques that are not necessary to those having ordinary skill in the art for a complete understanding of the aspects and features of the present inventive concept may not be described. Unless otherwise noted, like reference numerals denote like elements throughout the attached drawings and the written description, and thus, descriptions thereof will not be repeated. Further, parts not related to the description of the embodiments might not be shown to make the description clear. In the drawings, the relative sizes of elements, layers, and regions may be exaggerated for clarity.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the particular illustrated shapes of regions, but are to include deviations in shapes that result from, for instance, manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form in order to avoid unnecessarily obscuring various embodiments.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

It will be understood that when an element, layer, region, or component is referred to as being “on,” “connected to,” or “coupled to” another element, layer, region, or component, it can be directly on, connected to, or coupled to the other element, layer, region, or component, or one or more intervening elements, layers, regions, or components may be present. However, “directly connected/directly coupled” refers to one component directly connecting or coupling another component without an intermediate component. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of this disclosure, expressions such as “at least one of,” when preceding a list of elements, modify the entire list of elements and do not modify the individual elements of the list. For example, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. Like numbers refer to like elements throughout. As used herein, the term “and/or” includes any and all combinations of one or more of the associated listed items.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively. Also, the term “exemplary” is intended to refer to an example or illustration.

When a certain embodiment may be implemented differently, a specific process order may be performed differently from the described order. For example, two consecutively described processes may be performed substantially at the same time or performed in an order opposite to the described order.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

The electronic or electric devices and/or any other relevant devices or components according to embodiments of the present disclosure described herein may be implemented utilizing any suitable hardware, firmware (e.g. an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate. Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the embodiments of the present disclosure.

Unless otherwise defined, all terms (including technical and scientific terms) used herein have the same meaning as commonly understood by one of ordinary skill in the art to which the present inventive concept belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Hereinafter, a probe card and a test device including the same will be described with reference to embodiments in conjunction with the accompanying drawings.

FIG. 1 is a view illustrating a configuration of a test device according to an embodiment of the present disclosure.

Referring to FIG. 1, the test device according to the present embodiment may include a probe station 10, a probe card 20, and a measurer 30.

The probe station 10 may connect a main measuring apparatus and an object to be measured so as to measure an electrical characteristic of a display element. For example, the probe card 20 may be detached from, or attached to, the probe station 10. A signal connection line of the object to be measured may be connected using the attached probe card 20. In addition, the object to be measured may be fixed to the probe station 10.

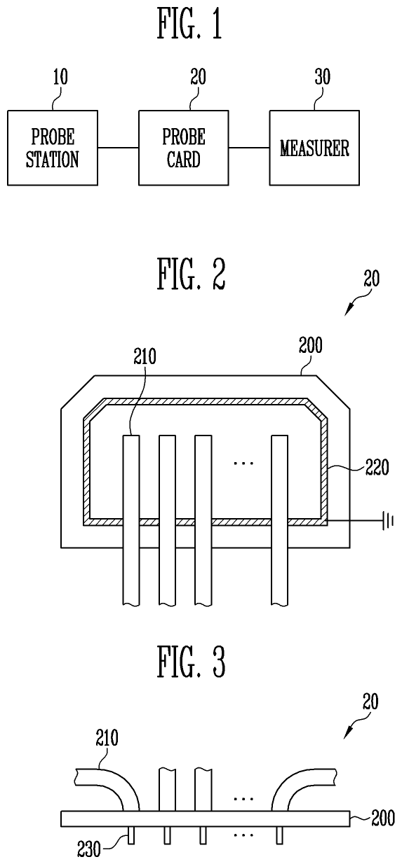

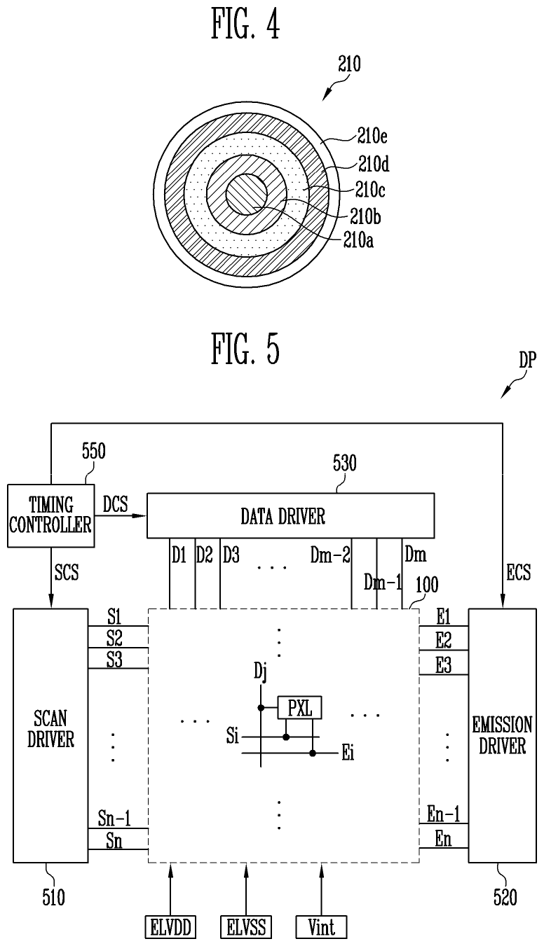

The probe card 20 is detachable from, or attachable to, the probe station 10 (e.g., may be selectively attachable to the probe station), and may electrically connect the object to be measured to the measurer 30. A configuration and function of the probe card 20 according to an embodiment of the present disclosure will be described in detail below with reference to FIGS. 2 and 3.

The measurer 30 may supply an electrical signal (e.g., a predetermined electrical signal) to the probe card 20, or may receive a signal including an electrical characteristic of the object to be measured from the probe card 20 so as to test the object to be measured, which is electrically connected through the probe card 20.

FIGS. 2 and 3 are views illustrating a configuration of the probe card according to an embodiment of the present disclosure. For example, FIG. 2 is a plan view when the probe card according to the present embodiment is viewed from the top, and FIG. 3 is a side view of the probe card according to an embodiment of the present disclosure.

Referring to FIGS. 2 and 3, the probe card 20 according to the present embodiment may include a probe substrate 200, a plurality of cables 210, a conductive line 220, and a plurality of pins 230.

The probe substrate 200 may fix, or hold, the plurality of cables 210 and the plurality of pins 230.

Meanwhile, in some embodiments of the present disclosure, the probe substrate 200 may include a printed circuit board on which electronic elements for controlling an inspection signal of the plurality of pins 230 are mounted.

The plurality of cables 210 may be located on the probe substrate 200, and each of the plurality of cables 210 may be electrically connected to a corresponding pin 230. When one end of each of the plurality of cables 210 is connected to the probe substrate 200, the other ends of the plurality of cables 210 may be connected to the measurer 30 shown in FIG. 1. The cables 210 may transfer an electrical signal generated by an object to be measured to the measurer 30.

In a probe card according to a conventional art, a cable is connected to a probe substrate through a predetermined connector, but a leakage current path is formed through the cable. On the other hand, in the probe card 20 according to the present embodiment, the plurality of cables 210 are directly connected to the probe substrate 200 without any separate connector. Accordingly, influence otherwise caused by leakage current can be reduced.

The conductive line 220 may be formed on the probe substrate 200. The conductive line 220 may be formed along an edge of the probe substrate 200, and may have a closed curve shape as shown in FIG. 2.

The plurality of cables 210 and/or the plurality of pins 230 may be located in an area surrounded by the conductive line 220.

The conductive line 220 may be connected to a ground line so as to maintain a ground potential. The ground line may be connected to a separate ground voltage supply source. Alternatively, the ground line may be connected to the measurer 30, which is connected to the ground voltage supply source.

The conductive line 220 maintains the ground potential, so that current can be prevented from being leaked to the outside of the probe substrate 200, or so that leakage current trapped in the probe substrate 200 can be discharged. That is, the conductive line 220 that maintains the ground potential is formed on the probe substrate 200, so that the influence caused by leakage current can be reduced or minimized.

Meanwhile, the conductive line 220 may be in a state in which it is electrically separated from the plurality of cables 210 and the plurality of pins 230.

The plurality of pins 230 may be provided on the probe substrate 200. When an electrical characteristic of an object to be measured is tested, the plurality of pins 230 may be in direct contact with the object to be measured.

Meanwhile, although a case where the plurality of cables 210 and the plurality of pins 230 are located on different surfaces of the probe substrate 200 is illustrated in FIGS. 2 and 3, the present disclosure is not limited thereto. The positions of the plurality of cables 210 and the plurality of pins 230 may be variously modified in other embodiments.

FIG. 4 is a sectional view of the cable shown in FIGS. 2 and 3.

Referring to FIG. 4, the cable 210 may include a conductive core 210a, a first protective layer 210b, an intermediate layer 210c, a second protective layer 210d, and a jacket 210e.

The conductive core 210a is located inside the cable 210, and may transfer (e.g., to the measurer 30 shown in FIG. 1) an electrical signal including, or indicating, an electrical characteristic of an object to be measured. The conductive core 210a may include a conductive material such as copper.

The first protective layer 210b may be formed to surround the conductive core 210a. However, in some cases, the first protective layer 210b may surround only a portion of the conductive core 210a such that a portion of the conductive core 210a is exposed to the outside of the first protective layer 210b.

Meanwhile, in other embodiments of the present disclosure, a dielectric layer including a dielectric material may be located between the conductive core 210a and the first protective layer 210b.

The intermediate layer 210c may be provided on the first protective layer 210b to surround the first protective layer 210b.

The second protective layer 210d may be provided on the intermediate layer 210c to surround the intermediate layer 210c. The first protective layer 210b and the second protective layer 210d may include a conductive material, such as silver or copper.

The jacket 210e may be provided on the second protective layer 210d to surround the second protective layer 210d. The intermediate layer 210c and the jacket 210e may include an insulating material, such as polyethylene or polyurethane.

An electrical characteristic of an element of a pixel circuit included in a display device, which will be described later, may be tested using the test device including the probe card 20 according to the present embodiment.

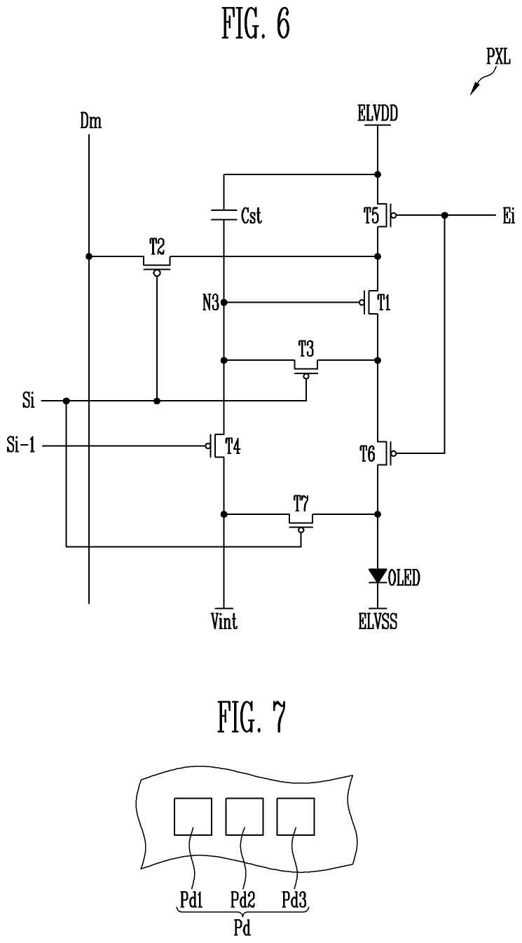

FIG. 5 is a view schematically illustrating a configuration of a display device.

Referring to FIG. 5, the display device DP may include a display unit 100, a scan driver 510, an emission driver 520, a data driver 530, and a timing controller 550.

The display device may include a plurality of pixels PXL. The plurality of pixels PXL may be connected to data lines D1 to Dm, scan lines S1 to Sn, and emission control lines E1 to En.

The pixels PXL may be supplied with a first power source ELVDD, a second power source ELVSS, and an initialization power source Vint, which may be externally supplied from the outside.

Each of the pixels PXL may be selected when a corresponding scan signal is supplied to a respective one of the scan lines S1 to Sn that is connected to the pixel PXL to thereby be supplied with a data signal from respective one of the data lines D1 to Dm, which is also connected to the pixels PXL. The pixel PXL supplied with the data signal may control an amount of current flowing to a light emitting element connected to the pixel corresponding to the data signal.

The light emitting element may generate light (e.g., light with a predetermined luminance) corresponding to the amount of current.

The timing controller 550 may generate a scan driving control signal SCS, a data driving control signal DCS, and an emission driving control signal ECS, based on externally supplied signals that are input from the outside. The scan driving control signal SCS generated by the timing controller 550 is supplied to the scan driver 510, the data driving control signal DCS generated by the timing controller 550 is supplied to the data driver 530, and the emission driving control signal ECS generated by the timing controller 550 is supplied to the emission driver 520.

The scan driver 510 may supply a scan signal to the scan lines S1 to Sn in response to the scan driving control signal SCS. For example, the scan driver 510 may sequentially supply the scan signal to the scan lines S1 to Sn.

The scan signal may be set to a gate-on voltage (e.g., a low level voltage) at which a corresponding transistor(s) included in the pixels PXL can be turned on.

The data driver 530 may supply a data signal to the data lines D1 to Dm in response to the data driving control signal DCS. The data signal supplied to the data lines D1 to Dm may be supplied to the pixels PXL to which the scan signal is supplied.

The emission driver 520 may supply an emission control signal to the emission control lines E1 to En in response to the emission driving control signal ECS. In an example, the emission driver 520 may sequentially supply the emission control signal to the emission control lines E1 to En.

When an emission control signal is supplied to the emission control lines E1 to En, the pixels PXL may not emit light. To this end, the emission control signal may be set to a gate-off voltage (e.g., a high level voltage) at which the transistors included in the pixels PXL can be turned off.

FIG. 6 is a view illustrating an embodiment of the pixel shown in FIG. 5. For convenience of description, a pixel PXL connected to an mth data line Dm and an ith scan line Si is illustrated in FIG. 6.

Referring to FIG. 6, the pixel PXL may include an organic light emitting element OLED, first to seventh transistors T1 to T7, and a storage capacitor Cst.

An anode of the organic light emitting element OLED may be connected to the first transistor T1 via the sixth transistor T6, and a cathode of the organic light emitting element OLED may be connected to the second power source ELVSS. The organic light emitting element OLED may generate light (e.g., light with a predetermined luminance) corresponding to an amount of current supplied from the first transistor T1.

The first power source ELVDD may be set to a voltage that is higher than that of the second power source ELVSS such that current can flow through the organic light emitting element OLED.

The seventh transistor T7 may be connected between the initialization power source Vint and the anode of the organic light emitting element OLED. In addition, a gate electrode of the seventh transistor T7 may be connected to the ith scan line Si. The seventh transistor T7 may be turned on when a scan signal is supplied to the ith scan line Si to thereby supply the voltage of the initialization power source Vint to the anode of the organic light emitting element OLED. The initialization power source may be set to a voltage that is lower than a data signal.

The sixth transistor T6 may be connected between the first transistor T1 and the organic light emitting element OLED. In addition, a gate electrode of the sixth transistor T6 may be connected to an ith emission control line Ei. The sixth transistor T6 may be turned off when an emission control signal is supplied to the ith emission control line Ei, and may be turned on otherwise.

The fifth transistor T5 may be connected between the first power source ELVDD and the first transistor T1. In addition, a gate electrode of the fifth transistor T5 may be connected to the ith emission control line Ei. The fifth transistor T5 may be turned off when an emission control signal is supplied to the ith emission control line Ei, and may be turned off otherwise.

A first electrode of the first transistor (driving transistor) T1 may be connected to the first power source ELVDD via the fifth transistor T5, and a second electrode of the first transistor T1 may be connected to the anode of the organic light emitting element OLED via the sixth transistor T6. In addition, a gate electrode of the first transistor T1 may be connected to a third node N3. The first transistor T1 may control an amount of current flowing from the first power source ELVDD to the second power source ELVSS via the organic light emitting element OLED, corresponding to a voltage of the third node N3.

The third transistor T3 may be connected between the second electrode of the first transistor T1 and the third node N3. In addition, a gate electrode of the third transistor T3 may be connected to the ith scan line Si. The third transistor T3 may be turned on when a scan signal is supplied to the ith scan line Si to thereby electrically connect the second electrode of the first transistor T1 and the third node N3. Therefore, when the third transistor T3 is turned on, the first transistor T1 may be diode-connected.

The fourth transistor T4 may be connected between the third node N3 and the initialization power source Vint. In addition, a gate electrode of the fourth transistor T4 may be connected to an (i−1)th scan line Si-1. The fourth transistor T4 may be turned on when a scan signal is supplied to the (i−1)th scan line Si-1 to thereby supply the voltage of the initialization power source Vint to the third node N3.

The second transistor T2 may be connected between the mth data line Dm and the first electrode of the first transistor T1. In addition, a gate electrode of the second transistor T2 may be connected to the ith scan line Si. The second transistor T2 may be turned on when a scan signal is supplied to the ith scan line Si to thereby electrically connect the mth data line Dm and the first electrode of the first transistor T1.

The storage capacitor Cst may be connected between the first power source ELVDD and the third node N3. The storage capacitor Cst may store a voltage corresponding to the data signal and a threshold voltage of the first transistor T1.

FIG. 7 is a view illustrating a pad for testing an electrical characteristic of an element included in the pixel. For example, FIG. 7 is an enlarged view illustrating a portion of a substrate used when the display device is fabricated.

An electrical characteristic of at least one element among the first to seventh transistors T1 to T7, the storage capacitor Cst, and the organic light emitting element OLED, which are included in the pixel PXL, may be tested using the test device including the probe card 20 according to the present embodiment.

To this end, when the display device is fabricated, a pad Pd may be formed at a portion of the outside of the substrate on which the components of the display device are mounted.

For example, when an electrical characteristic of the first transistor T1 is to be tested, a transistor having the same standard as the first transistor T1 may be formed together with the first transistor T1 at a portion of the outside of the substrate when the display device is fabricated. Next, the pad Pd may be formed as shown in FIG. 7 to be electrically connected to the electrodes of the transistor.

That is, the first electrode of the transistor may be connected to a first pad Pd1, the second electrode of the transistor may be connected to a second pad Pd2, and the gate electrode of the transistor may be connected to a third pad Pd3.

When the plurality of pins 230 included in the probe card 20 are in contact with the first to third pads Pd1 to Pd3, respectively, an electrical signal including an electrical characteristic of the transistor may be transmitted to the measurer 30 via the plurality of cables 210.

In the case of transistors included in an organic light emitting display device, the transistor is generally formed to have a low off current (drain current when any voltage is not applied to a gate electrode of the transistor, i.e., when the transistor is in a turn-off state). Therefore, a probe card capable of easily controlling leakage current is to be used so as to accurately test an electrical characteristic of the transistor.

In the case of a test device including the probe card according to the conventional art, the amount of leakage current generated in the probe card becomes about 100 (fA) to about 300 (fA), and therefore, it is difficult to accurately measure an electrical characteristic of a transistor having a low off-current characteristic. However, as described above, in the probe card according to the present embodiment, the influence caused by leakage current is reduced or minimized, and thus an electrical characteristic of a transistor having a low-off current characteristic can be accurately measured.

According to the present disclosure, leakage current generated in the probe card and the test device including the same is reduced, so that an electrical characteristic of a display element can be accurately tested.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present disclosure as set forth in the following claims, with functional equivalents thereof to be included.

What is claimed is:

1. A probe card comprising:
a probe substrate;
a plurality of cables on the probe substrate;
a plurality of pins on the probe substrate, the plurality of pins being electrically connected to the plurality of cables; and
a conductive line on the probe substrate, the conductive line being connected to a ground line.

2. The probe card of claim 1, wherein the conductive line is formed along an edge of the probe substrate.

3. The probe card of claim 2, wherein the conductive line has a closed curve shape.

4. The probe card of claim 3, wherein the plurality of cables are located in an area surrounded by the conductive line.

5. The probe card of claim 1, wherein each of the plurality of cables comprises:
a conductive core;
a first protective layer on the conductive core;
an intermediate layer on the first protective layer;
a second protective layer on the intermediate layer; and
a jacket on the second protective layer.

6. The probe card of claim 5, wherein the conductive core is directly connected to the probe substrate.

7. A test device comprising:
a probe station for fixing an object to be measured;
a probe card configured to be attached to the probe station to be electrically connected to the object to be measured; and
a measurer configured to be connected to the probe card for measuring an electrical characteristic of the object to be measured,
wherein the probe card comprises:
a probe substrate;
a plurality of cables on the probe substrate, and configured to be connected to the measurer;
a plurality of pins on the probe substrate and electrically connected to the plurality of cables; and
a conductive line on the probe substrate and connected to a ground line.

8. The test device of claim 7, wherein the ground line is configured to be connected to the measurer.

9. The test device of claim 7, wherein the conductive line is formed along an edge of the probe substrate.

10. The test device of claim 9, wherein the conductive line has a closed curve shape.

11. The test device of claim 10, wherein the plurality of cables are located in an area surrounded by the conductive line.

12. The test device of claim 7, wherein each of the plurality of cables comprises:
a conductive core;
a first protective layer on the conductive core;
an intermediate layer on the first protective layer;
a second protective layer on the intermediate layer; and
a jacket on the second protective layer.

13. The test device of claim 12, wherein the conductive core is configured to be directly connected to the probe substrate.

14. The test device of claim 7, wherein the object to be measured is at least one of a transistor and a capacitor that are comprised in a pixel in an organic light emitting display device.

15. The test device of claim 14, wherein the plurality of pins are configured to be in direct contact with the object to be measured.
